(19) United States
(12) Patent Application Publication
(10) Pub. No.: US 2010/0151684 A1
(43) Pub. Date: Jun. 17, 2010

(54) SLURRY COMPOSITION FOR PRIMARY CHEMICAL MECHANICAL POLISHING AND CHEMICAL MECHANICAL POLISHING METHOD

(75) Inventors: Eun-Mi CHOI, Daejeon (KR); Dong-Mok SHIN, Daejeon (KR); Seung-Beom CHO, Daejeon (KR)

Correspondence Address: ROTHWELL, FIGG, ERNST & MANBECK, P.C., 1425 K STREET, N.W., SUITE 800, WASHINGTON, DC, 20005, US

(73) Assignee: LG CHEM LTD., Seoul (KR)

(21) Appl. No.: 12/630,556

(22) Filed: Dec. 3, 2009

(30) Foreign Application Priority Data
Dec. 3, 2008 (KR) 10-2008-0122084

(51) Int. Cl. H01L 21/306; C09K 13/00; C09K 13/06

(52) U.S. Cl. 438/693; 252/79.1; 252/79.4; 257/E21.23

(57) ABSTRACT

The present invention relates to a slurry composition for primary chemical mechanical polishing that can show more improved WIWNU (Within Wafer Non-Uniformity) while exhibiting excellent polishing rate and polishing selectivity, and a chemical mechanical polishing method. The slurry composition for primary chemical mechanical polishing comprises an abrasive; an oxidant, an organic acid; a specific corrosion inhibitor, and, a polymeric additive comprising polyvinylpyrrolidone having weight average molecular weight of about 3000 to 100000, and has polishing selectivity of polishing rates between a copper layer:a tantalum layer of about 30:1 or more.

### CROSS REFERENCE TO RELATED APPLICATION

The present application claims priority to and the benefit of Korean patent application No. 2008-0122084 filed in the Korea Intellectual Property Office on Dec. 3, 2008, the entire content of which is incorporated herein by reference.

### BACKGROUND OF THE INVENTION

(a) Field of the Invention

The present invention relates to a slurry composition for primary chemical mechanical polishing (CMP) and a chemical mechanical polishing method.

(b) Description of the Related Art

High integration and high performance of a semiconductor device have continuously been required. Particularly, it is necessarily required to form a multi-layered wiring structure in order to achieve the high performance of the semiconductor device, and a planarization of each wiring layer is required in order to form the multi-layered wiring structure.

From the past, various methods of a reflow, a spin-on-glass (SOG) or an etchback, and the like have been used for the planarization of the wiring layer; however, these methods did not show satisfactory results according to the formation of the multi-layered wiring structure. Thus, recently, chemical mechanical polishing (CMP) method is most widely applied for the planarization of the wiring layer.

The CMP method is a method of contacting a polishing pad with a wiring layer and moving them relatively (for example, rotating a substrate on which the wiring layer is formed) while providing a slurry composition comprising an abrasive and various chemical constituents between the polishing pad of the polishing device and the substrate on which the wiring layer is formed, so as to polish the wiring layer chemically by the action of the chemical constituents while mechanically polishing the wiring layer with the abrasive.

Recently, in order to further decrease resistance of the wiring layer and achieve high performance of a semiconductor device, there is a tendency to form the wiring layer with copper having low resistance. The polishing and planarization of the copper wiring layer by CMP method are generally progressed as follows.

First, after forming an insulating layer such as a silicon oxide layer and a polishing stop layer, a copper wiring layer is formed on the polishing stop layer. At this time, the thickness of the copper wiring layer to be polished is defined by the polishing stop layer, and the copper wiring layer is planarized by removing the copper wiring layer formed on the polishing stop layer by polishing.

After forming the copper wiring layer, polishing and planarization are conducted by 2-steps CMP method. In primary polishing step, most of the copper wiring layer on the polishing stop layer is removed, and the primary polishing is stopped when the upper surface of the polishing stop layer is exposed. Then, in secondary polishing step, the surfaces of the polishing stop layer of which upper surface is exposed, the insulating layer and the copper wiring layer are finely polished to control fine uniformity and roughness of the copper wiring layer and remove dishing or erosion generated in the primary polishing step, thereby obtaining a planarized copper wiring layer. At this time, dishing or erosion refers to a phenomenon that a part of the copper wiring layer or the insulating layer is removed at a part that should not be removed by polishing to generate a depressed part on the polishing surface. The dishing or erosion may deteriorate electrical property of the copper wiring layer, etc.

In the above explained polishing and planarization method of the copper wiring layer, most of the copper wiring layer on the polishing stop layer is removed in the primary polishing step, and the polishing should be stopped when the upper surface of the polishing stop layer is exposed so as to prevent damage to the insulating layer, etc. Thus, a slurry composition used in the primary polishing step is required to have high polishing rate to the copper wiring layer and low polishing rate to the polishing stop layer to show excellent polishing selectivity to the copper wiring layer against the polishing stop layer, and not to generate much dishing or erosion that may cause deterioration of electrical property of the polished copper wiring layer.

To the contrary, in the secondary polishing step, the whole surface that has been primarily polished, i.e., the surfaces of the polishing stop layer, the insulating layer and the copper wiring layer are finely polished to control roughness and remove dishing or erosion. Thus, a slurry composition used in the secondary polishing step is required to have relatively low polishing rate and polishing selectivity to the copper wiring layer and generally similar polishing rates between the polishing stop layer, the insulating layer and the copper wiring layer.

In order to satisfy the above requirements, aqueous slurry compositions comprising an abrasive, an oxidant and an organic acid suitable for each chemical mechanical polishing step have been classified into slurry compositions for primary and secondary chemical mechanical polishing and used, and the requirements in the primary and secondary polishing steps have been satisfied by the separate use of the slurry compositions.

However, it has been found that if a previously known slurry composition for primary polishing is used, the slurry cannot be smoothly flown in and discharged at polishing, thus generating excessive removal of the copper wiring layer at the edge of the wafer compared to the central part of the wafer. This may cause large deterioration of WIWNU (Within Wafer Non-Uniformity) of the primarily polished copper wiring layer, and the excessive removal of the copper wiring layer, etc. at a part that needs not to be removed may largely increase dishing or erosion. Thus, the progress of secondary polishing after primary polishing may be difficult, and reliability or property of the copper wiring layer and a device comprising the same may be largely deteriorated.

### SUMMARY OF THE INVENTION

It is an aspect of the present invention to provide a slurry composition for primary chemical mechanical polishing that can show more improved WIWNU (Within Wafer Non-Uniformity), while exhibiting excellent polishing rate and polishing selectivity.

It is another aspect of the present invention to provide a chemical mechanical polishing method (CMP method) conducting primary chemical mechanical polishing using the slurry composition.

The present invention provides a slurry composition for primary chemical mechanical polishing which comprises an abrasive; an oxidant; an organic acid; at least one kind of corrosion inhibitor selected from the group consisting of a pyridine-based compound, a pyrazole-based compound, and a quinoline-based compound; and, a polymeric additive comprising polyvinylpyrrolidone having weight average molecular weight of about 3000 to 100000, and has polishing selectivity of polishing rates between a copper layer:a tantalum layer of about 30:1 or more.

The present invention also provides a chemical mechanical polishing method comprising: contacting a polishing pad with a copper-containing layer and moving them relatively while providing the above slurry composition between the copper-containing layer on the substrate and the polishing pad so as to primarily polish the copper-containing layer.

### BRIEF DESCRIPTION OF THE DRAWINGS

FIG. 1 is a graph showing distribution and difference of polishing amount at each point on a wafer on which a copper layer is formed, when polishing the copper layer using the slurry compositions of Examples 1, 2, 9 and 10 and Comparative Examples 1 and 2.

### DETAILED DESCRIPTION OF THE EMBODIMENTS

Hereinafter, the slurry composition for primary CMP according to embodiments of the invention and the CMP method using the same are explained in more detail.

Unless otherwise described, the terms used herein are defined as follow.

The term “primary chemical mechanical polishing” or “primary CMP” used herein refers to a first step of polishing a target layer by a CMP method, when polishing or planarizing a target layer such as a copper wiring layer. In the “primary chemical mechanical polishing” or “primary CMP” step, as well known in the art, most of the target layer (for example, about 70% or more, or about 90% or more of the target layer) may be removed.

And, the term “slurry for primary chemical mechanical polishing” or “slurry for primary CMP” used therein refers to a slurry for CMP provided and used for polishing in the above-explained “primary chemical mechanical polishing” or “primary CMP”. The slurry may exhibit high polishing rate to the target layer so as to rapidly and selectively remove most of the target layer, for example, the target layer on a polishing stop layer, and it may exhibit low polishing rate to the polishing stop layer so as to show high polishing selectivity to the target layer against the polishing stop layer. For this, the “slurry for primary chemical mechanical polishing” or the “slurry for primary CMP” comprises an abrasive, an oxidant and an organic acid, and it may show polishing rate to the copper layer of about 1000 Å/min or more, or about 3000 Å/min or more, and it may show polishing rate to the copper layer of over about 10 times or over about 30 times more than the polishing rate to a tantalum layer, thus showing polishing selectivity between the copper layer:the tantalum layer of about 10:1 or more, or about 30:1 or more.

And, the term “secondary chemical mechanical polishing” or “secondary CMP” used herein refers to a subsequent step of polishing the target layer such as a copper wiring layer by a CMP method, after conducting the above explained “primary chemical mechanical polishing” or “primary CMP”. In the “secondary chemical mechanical polishing” or “secondary CMP”, as well known in the art, the target layer or the surface of the polishing stop layer that has been polished in the “primary chemical mechanical polishing” or “primary CMP” step may be finely polished so as to control fine uniformity and roughness of a polished surface including the target layer. Thus, in the “secondary chemical mechanical polishing” or “secondary CMP” step, remaining thickness of the target layer that has not been removed in the “primary chemical mechanical polishing” or “primary CMP” (for example, about 30% or less, or about 10% or less of the target layer) may be removed.

And, the term “slurry for secondary chemical mechanical polishing” or “slurry for secondary CMP” refers to a slurry for CMP provided and used for polishing in the above explained “secondary chemical mechanical polishing” or “secondary CMP”. The slurry may exhibit relatively low polishing rate to the target layer and generally similar polishing rates between the target layer and the polishing stop layer, so as to finely polish the polished surface such as the target layer and the polishing stop layer that has been polished in the “primary CMP” step thus controlling fine uniformity and roughness, thereby showing low polishing selectivity to the target layer against the polishing stop layer. For this, the “slurry for secondary chemical mechanical polishing” or the “slurry for secondary CMP” may exhibit polishing rate to the copper layer of about 1000 Å/min or less or about 500 Å/min or less, and it may show polishing rate to the copper layer of below about 10 times or below about 5 times of the polishing rate to a tantalum layer, thus showing polishing selectivity between the copper layer:the tantalum layer of about 10:1 or less, or about 5:1 or less.

Meanwhile, according to one embodiment of the invention, provided is a “slurry composition for primary chemical mechanical polishing (CMP)” used for “primary chemical mechanical polishing (CMP)” as above defined. The slurry composition for primary CMP comprises an abrasive; an oxidant; an organic acid; at least one kind of a corrosion inhibitor selected from the group consisting of a pyridine-based compound, a pyrazole-based compound, and a quinoline-based compound; and, a polymeric additive comprising polyvinylpyrrolidone having weight average molecular weight of 3000 to 100000, and has polishing selectivity of polishing rates between a copper layer:a tantalum layer of 30:1 or more,

Since the slurry composition for primary CMP comprises an abrasive, an oxidant, an organic acid and a specific corrosion inhibitor, it exhibits high polishing rate to the target layer, for example a copper-containing layer such as a copper wiring layer, and low polishing rate to a tantalum-containing layer (for example, tantalum nitride layer) that is used as a polishing stop layer when polishing a copper wiring layer, thus showing high polishing selectivity to the copper layer against the tantalum layer (about 30:1 or more). Particularly, as results of the experiments of the inventors, it was found that when a pyridine-based compound, a pyrazole-based compound or a quinoline-based compound is used as a corrosion inhibitor instead of previously used triazole-based compound such as benzotriazole, the corrosion inhibitor may effectively inhibit dishing or erosion of the polished copper-containing layer without deteriorating polishing rate to the copper-containing layer. Therefore, the slurry composition can show high polishing rate and excellent polishing selectivity to the copper-containing layer, and thus, when applied for CMP of a target layer such as a copper wiring layer, it can rapidly and selectively remove the target layer.

And, as results of the experiments of the inventors, it was found that when polyvinylpyrrolidone having specific molecular weight is included in the slurry composition for primary CMP, WIWNU (Within Wafer Non-Uniformity) of primarily polished copper wiring layer can be largely improved. It appears that the polyvinylpyrrolidone acts as a wetting agent to enable the slurry composition for primary CMP to show more improved mobility between a wafer and a polishing pad of a polishing device. Thus, the slurry composition can be uniformly dispersed and penetrated over a large area between the wafer and the polishing pad to improve WIWNU (Within Wafer Non-Uniformity). And, by the addition of the polyvinylpyrrolidone, a copper wiring layer can be uniformly polished over the whole area of a wafer, and excessive removal of the copper wiring layer at the edge of the wafer can be inhibited, thereby reducing dishing or erosion of the copper wiring layer.

Accordingly, the slurry composition for primary CMP can show more improved WIWNU (Within Wafer Non-Uniformity) while showing high polishing rate and excellent polishing selectivity to a target layer, and it can largely reduce dishing or erosion generated by unnecessary removal of the target layer, for example, a copper wiring layer at the edge of a wafer, thus enabling manufacture of semiconductor devices having more improved properties.

Therefore, the slurry composition for primary CMP can be preferably used for primary CMP of a copper wiring layer of a semiconductor device.

Hereinafter, each constituent of the slurry composition for primary CMP is explained in more detail.

The slurry composition for primary CMP comprises an abrasive for mechanical polishing of the target layer. Common abrasives those have been used to the slurry composition for CMP may be used without specific limitations, and for example, a metal oxide abrasive, an organic abrasive, or an organic-inorganic complex abrasive may be used.

For example, a silica abrasive, an alumina abrasive, a ceria abrasive, a zirconia abrasive, or a titania abrasive may be used as the metal oxide abrasive, and 2 or more kinds of abrasives selected from them may be used. Furthermore, the metal oxide abrasive prepared by any method, such as a fuming method, a sol-gel method, and the like may be used without specific limitations.

Furthermore, a styrene-based polymer abrasive such as a polystyrene or a styrene-based copolymer, an acryl-based polymer abrasive such as a polymethacrylate, a acryl-based copolymer or a methacrylate-based copolymer, polyvinylchloride a, polyamide abrasive, a polycarbonate abrasive, a polyimide abrasive, and the like may be used without specific limitations as the organic abrasive, and the spherical polymer abrasive having a single structure or a core/shell structure consisting of the polymer selected from them may be used without limitations in their shape. Furthermore, the polymer abrasive obtained by any method such as an emulsion polymerization or a suspension polymerization may be used as the organic abrasive.

Furthermore, it is needless to say that the organic-inorganic complex abrasive formed by compounding the organic materials such as the polymers, and the inorganic materials such as the metal oxides, can be also used as the abrasive.

However, it is preferable to use the silica abrasive as the abrasive in terms of polishing rate or polishing speed to the target layer such as a copper wiring layer or the proper surface protection.

Furthermore, the abrasive may have an average diameter of 10 to 500 nm by considering the proper polishing speed to the target layer and dispersion stability in the slurry composition. For example, the average diameter of primary particles of the abrasive may be 10 to 200 nm, and preferably 10 to 100 nm based on a SEM measurement when the metal oxide abrasive is used, and the average diameter of primary particles of the abrasive may be 10 to 500 nm, and preferably 50 to 300 nm when the organic abrasive is used. The polishing speed to the target layer may be decreased when the size of the abrasive becomes excessively small, and, on the contrary, the dispersion stability of the abrasive in the slurry composition may be decreased when the size becomes excessively large.

The abrasive may be included in the slurry composition for CMP in the content of about 0.1 to 30 wt %, preferably about 0.5 to 10 wt %, more preferably about 0.5 to 2 wt %.

Furthermore, the slurry composition for primary CMP comprises an oxidant. The oxidant forms an oxide film by oxidizing the target layer such as a copper wiring layer, and the polishing process of the CMP method is progressed to the target layer by eliminating the oxide film by physical and chemical polishing process.

Common oxidants those have been used to the slurry composition for CMP may be unlimitedly used as the oxidant, and for examples, an organic peroxide-based compound such as hydrogen peroxide, peracetic acid, perbenzoic acid, tert-butylhydroperoxide, and the like; ammonium persulfate (APS), potassium persulfate (KPS), hypochlorous acid, potassium permanganate, iron nitrate, potassium ferricyanide, potassium periodate, sodium hypochlorite, vanadium trioxide, potassium bromated, and the like may be used as the oxidant. Among the various oxidants, ammonium persulfate may be preferable because it can inhibit dishing or erosion generated by unnecessary removal of the part of the target layer such as a copper wiring layer that needs not to be polished or removed in the primary CMP.

The oxidant may be included in the slurry composition for CMP in the content of about 0.1 to 10 wt %, preferably about 0.1 to 5 wt %, more preferably about 0.2 to 3 wt %. The polishing rate to the target layer may be decreased when the content of the oxidant is excessively low, and the property of the copper wiring layer may be deteriorated when the content of the oxidant is excessively high because the surface of the target layer may be excessively oxidized or corroded and sectional corrosions remain on the finally polished target layer such as the copper wiring layer.

The slurry composition for CMP also comprises an organic acid. The organic acid forms a complex with a metallic substance such as copper of the target layer that is oxidized by the action of the oxidant to eliminate the copper ions, and improves the polishing rate to the target layer. Particularly, the chemical polishing by the interaction of the organic acid and the oxidant may be a main mechanism of polishing the target layer, when the target layer is a copper wiring layer,

As the organic acid, an amino acid, an amine-based compound, a carboxylic acid compound, and the like may unlimitedly be used. As specific examples of the organic acid, amino acid such as alanine, glycine, cystine, or histidine; an amine-based compound such as asparagine, guanidine, hydrazine, or ethylene diamine; a carboxylic acid compound such as maleic acid, malic acid, tartaric acid, citric acid, malonic acid, phthalic acid, acetic acid, lactic acid, pyridine carboxylic acid, pyridine dicarboxylic acid, or a salt thereof may be used. Among them, considering the reactivity to a target layer such as a copper wiring layer, alanine, glycine, malic acid, phthalic acid, pyridine carboxylic acid, pyridine dicarboxylic acid, or a salt thereof may be preferably used, and glycine may be more preferable. When the preferable organic acid is used, polishing rate to the target layer such as a copper wiring layer can be more improved, and particularly, polishing rate to the target layer can be more improved compared to other thin layers such as a tantalum layer, to further improve polishing selectivity.

The organic acid may be included in the slurry composition for primary CMP in the content of about 0.05 to 2 wt %, preferably about 0.1 to 1 wt %, more preferably about 0.5 to 1.5 wt %. Within these contents, it is possible to reduce dishing or erosion generated on the surface of the target layer after polishing, while optimizing polishing speed to the target layer.

Meanwhile, the slurry composition for primary CMP comprises a corrosion inhibitor as another constituent. Particularly, the slurry composition comprises at least one kind of a corrosion inhibitor selected from the group consisting of a pyridine-based compound, a pyrazole-based compound or a quinoline-based compound.

The corrosion inhibitor is added in order to prevent the target layer from being excessively chemically attacked by an organic acid at the dug parts thereof to inhibit dishing and the like. However, it was found that a triazole-based compound such as benzotriazole that has been previously used as a corrosion inhibitor may inhibit polishing rate of the slurry to the target layer. To the contrary, it was found that the pyridine-based compound, pyrazole-based compound, or quinoline-based compound can effectively inhibit dishing or erosion of the target layer after polishing without deteriorating polishing rate to the target layer.

Accordingly, the slurry composition for primary CMP according to one embodiment of the invention comprises the pyridine-based compound, pyrazole-based compound, or quinoline-based compound as a corrosion inhibitor, to effectively inhibit dishing and the like of the target layer while exhibiting high polishing rate to the target layer such as a copper-containing layer.

As the pyridine-based compound, pyrazole-based compound, or quinoline-based compound, 4,4′-dipyridyl ethane, 4,4′-dipyridyl ethene, 4,4′-dipyridyl propane, 4,4′-dipyridyl propene, 3,5-pyrazole dicarboxylic acid, quinaldic acid, 2-quinazoline carboxylic acid, 4-quinazoline carboxylic acid, 2-quinoline carboxaldehyde, 8-quinolinol, 2-quinolinol, and a salt thereof may be used. In addition, various pyridine-based compounds, pyrazole-based compounds or quinoline-based compounds known to be useable as a corrosion inhibitor for a CMP slurry may be used.

Furthermore, the corrosion inhibitor may be included in the slurry composition for primary CMP in the content of about 0.001 to 2 wt %, preferably about 0.01 to 1 wt %, more preferably about 0.1 to 0.5 wt %. Thereby, dishing and the like caused by the chemical attack of the organic acid may be effectively reduced, while reducing deterioration of polishing rate to the target layer caused by the corrosion inhibitor.

Meanwhile, the slurry composition for primary CMP according to one embodiment of the invention further comprises a polymeric additive comprising polyvinylpyrrolidone having weight average molecular weight of about 3000 to 100000, preferably about 3000 to 60000 in addition to the constituents described above. As results of the experiments of the inventors, it was found that when the slurry composition for primary CMP comprises the polymeric additive, the polymeric additive acts as a wetting agent to aid each constituent of the slurry composition for primary CMP to be uniformly dispersed and penetrated over the large area of the wafer on the surface of a polishing pad and to further improve chemical polishing effect by each constituent of the slurry composition. Therefore, by the polymeric additive comprising the polyvinylpyrrolidone, polishing in primary CMP using the slurry composition can be more uniformly and effectively conducted over the wafer, and thus, WIWNU of the target layer can be further improved in the process of the primary CMP. Particularly, as results of the experiments of the inventors, it was found that when a slurry composition for primary composition comprising the polyvinylpyrrolidone is used, WIWNU of the target layer of copper wiring layer becomes about 5% or less, to exhibit very excellent uniformity.

Accordingly, if the slurry composition for primary CMP is used to conduct primary CMP process, dishing or erosion generated by unnecessary removal of the target layer such as a copper wiring layer at the edge of the wafer can be inhibited, and semiconductor device having more improved properties can be manufactured.

Meanwhile, the slurry composition for primary CMP according to one embodiment of the invention may further comprise other kinds of polymeric additives such as propyleneoxide-ethyleneoxide copolymer, polyethyleneglycol or polyoxyethylene ether (product name: BRIJ series) and the like. The polishing properties such as polishing rate or polishing selectivity of the slurry composition for primary CMP can be controlled using the polymeric additives. Particularly, using the additional polymeric additives, polishing rate to the target layer such as a copper wiring layer can be further improved, and polishing rate to the target layer can be further improved compared to other thin layers such as a tantalum layer to further improve polishing selectivity to the target layer.

The polymeric additive comprising polyvinylpyrrolidone may be included in the slurry composition for primary CMP in the content of about 0.0001 to 1 wt %, preferably about 0.001 to 1 wt %, more preferably about 0.01 to 0.5 wt %, most preferably about 0.05 to 0.5 wt %. And, as explained above, the polymeric additive may further comprise other kinds of polymeric additives in addition to the polyvinylpyrrolidone, in which case, the polyvinylpyrrolidone may be included in the slurry composition for primary CMP in the content of about 0.0001 to 1 wt %, preferably about 0.001 to 0.5 wt %, and other kinds of additives may be included in the content of about 0.0001 to 1 wt %, preferably about 0.001 to 0.5 wt %, more preferably 0.1 to 0.3 wt %. Within these contents of the polymeric additives, WIWNU of the target layer can be further improved in the primary CMP process, while maintaining excellent polishing rate and polishing selectivity to the target layer such as a copper wiring layer in the primary CMP process using the slurry composition for primary CMP.

Furthermore, the slurry composition for primary CMP may further comprise dodecylbenzenesulfonic acid (DBSA), dodecylsulfate (DSA) or a salt thereof in order to increase solubility of the polymeric additives.

In addition, the slurry composition for primary CMP according to one embodiment of the invention may further comprise a pH control agent in addition to the constituents described above, in order to control the pH of the slurry adequately.

As the pH control agent, at least one basic pH control agent such as potassium hydroxide, sodium hydroxide, aqueous ammonia, rubidium hydroxide, cesium hydroxide, sodium hydrogen carbonate, and sodium carbonate; or at least one acidic pH control agent selected from the group consisting of hydrochloric acid, nitric acid, sulfuric acid, phosphoric acid, formic acid, and acetic acid may be used, and the slurry may be diluted with a deionized water in order to prevent the coagulation of the slurry caused by a local pH variation when using a strong acid or a strong base.

Considering proper pH of the slurry composition to be controlled, a man skilled in the related art may use the pH control agent with a proper content.

Furthermore, the slurry composition for primary CMP may be in the form of an aqueous slurry composition likely to a common slurry composition for CMP. Thus, the slurry composition for primary CMP may further comprise water or an aqueous solvent as a solvent for dissolving or dispersing the constituents disclosed above in the remaining content.

The above explained slurry composition for primary CMP exhibits excellent polishing rate to a target layer such as a copper wiring layer, and to the contrary, low polishing rate to a tantalum-containing layer and the like that is used as a polishing stop layer when polishing the copper wiring layer, thus showing very high polishing selectivity to the target layer against the polishing stop layer. For example, according to the experiment results of the inventors, the slurry composition for primary CMP exhibits excellent polishing rate to a copper layer of about 3000 Å/min or more or about 4000 Å/min or more, for example, about 3000˜15000 Å/min, and it shows excellent polishing selectivity of polishing rates between the copper layer:the tantalum layer of about 30:1 or more, or about 40:1 or more, or about 40:1˜3000:1, or about 50:1˜700:1. And, the slurry composition for primary CMP shows very high polishing selectivity to a copper layer against a silicon oxide layer that is used as an insulating layer of a semiconductor device, for example, polishing rates between the copper layer:the silicon oxide layer of about 30:1 or more, or about 100:1 or more, or about 200:1˜1000:1.

Therefore, when the above slurry composition for primary CMP is used for primary CMP of a copper wiring layer of a semiconductor device, a target, i.e., a copper wiring layer on a polishing stop layer can be rapidly and selectively polished and removed to planarize it.

Furthermore, as results of experiments of the inventors, it was found that since the above explained slurry composition for primary CMP comprises a specific polymeric additive, after primary CMP using the slurry composition, WIWNU of the target layer such as a copper wiring layer may be very excellent as about 5% or less, preferably about 4.8% or less, more preferably about 1.5-4.8%, most preferably about 1.7-4.7%.

Accordingly, if the slurry composition for primary CMP is used for primary CMP of a copper wiring layer of a semiconductor device, the target of the copper wiring layer can be uniformly and effectively polished and removed over the whole wafer, and thus the polished copper wiring layer may exhibit excellent uniformity and property. Particularly, unnecessary removal of the copper wiring layer at the edge of the wafer may be inhibited to largely reduce dishing or erosion of the copper wiring layer polished by the primary CMP.

Therefore, the slurry composition for primary CMP can be preferably used to polish or planarize a target layer such as a copper wiring layer of a semiconductor device by primary CMP.

Thus, according to another embodiment of the invention, a chemical mechanical polishing method (CMP method) of a copper-containing layer using the above explained slurry composition is provided. The method comprises the step of contacting a polishing pad with a copper-containing layer and moving them relatively while providing the above explained slurry composition between the copper-containing layer on the substrate and the polishing pad so as to primarily polish the copper-containing layer.

In the CMP method, the copper-containing layer may be a copper wiring layer of a semiconductor device, and a polishing stop layer including tantalum may be formed below the copper wiring layer. Furthermore, the polishing stop layer and the copper wiring layer may be formed on an insulating layer composed of a silicon oxide layer.

In polishing or planarizing the copper-containing layer such as the copper wiring layer by CMP method, a substrate on which the copper-containing layer is formed is positioned at the head part of a polishing device, and the copper-containing layer and a polishing pad are contacted and moved relatively (that is, rotating the substrate on which the copper-containing layer is formed, or rotating the polishing pad) while providing the above explained slurry composition therebetween with facing them each other. Thereby, a mechanical polishing by the friction with the abrasive included in the slurry composition or the polishing pad, and a chemical polishing by the other chemical constituents of the slurry composition arise together, and the copper-containing layer is polished, and the polishing or planarization of the copper-containing layer may be completed by polishing the copper-containing layer until the upper surface of the polishing stop layer is exposed.

Particularly, in the CMP method according to another embodiment of the invention as explained above, a primary CMP process of the copper-containing layer is conducted using the slurry composition for CMP according to one embodiment of the invention. Thereby, the copper-containing layer can be rapidly polished, excellent polishing selectivity between the copper wiring layer and the polishing stop layer including a tantalum layer may be obtained, and the copper wiring layer can be polished or planarized more selectively and effectively while inhibiting damage to the insulating layer below the polishing stop layer. And, since the copper-containing layer polished by the primary CMP process can be polished or planarized more uniformly over the whole wafer, dishing or erosion of the copper-containing layer can be inhibited, and more excellent electrical properties or surface condition of the polished copper-containing layer can be obtained.

Therefore, it is possible to form a more reliable copper wiring layer of a semiconductor device more effectively by the CMP method, and it can largely contribute to the manufacture of a high-performance semiconductor device.

Meanwhile, the CMP method, after conducting the primary CMP process to the copper-containing layer by the above explained method, may further comprise a secondary CMP step to the copper-containing layer. In the secondary CMP process, a common aqueous slurry composition for secondary CMP, which has different compositions from the above explained slurry composition for primary CMP (for example, the kind or content of the abrasive, oxidant or organic acid may be different), shows polishing rate to the copper layer of about 1000 Å/min or less, or about 500 Å/min or less, and shows polishing selectivity between the copper layer to the tantalum layer of about 10:1 or less, or about 5:1 or less, may be used. And, the copper-containing layer may be secondarily polished by contacting a polishing pad with the copper-containing layer and moving them relatively while providing the above slurry composition therebetween.

By the secondary CMP process, fine uniformity or roughness of the surface polished in the primary CMP process can be controlled. However, in the CMP method according to another embodiment of the invention, since the surface including a copper-containing layer polished by primary CMP process maintains excellent WIWNU, the secondary CMP process can be conducted more easily and effectively.

Furthermore, in the secondary CMP process, an aqueous slurry composition for secondary CMP comprising a phosphorous-containing compound and abrasive may be used, the examples of which are disclosed in for example, Korean Laid-Open Patent Publication No. 2007-0063627 or No. 2007-0029079.

Meanwhile, in the CMP method, any polishing device for CMP can be used without specific limitations, and thus, polishing or planarization to the copper-containing layer by CMP can be conducted by relatively moving a polishing pad and a substrate on which the copper-containing layer is formed by any methods without specific limitations.

For examples, a polishing device in which a polishing platen and a polishing pad are not rotated and only the head part is rotated, can be used for CMP. When using this type of device in the CMP method, the copper-containing layer on the substrate can be polished by contacting a polishing pad with the copper-containing layer and rotating only the substrate on which the copper-containing layer is formed on the polishing pad without rotating the polishing pad. When a polishing device for CMP wherein a head part is rotated together with a polishing platen and a polishing pad, however, the copper-containing layer can be polished by rotating the polishing pad and the substrate on which the copper-containing layer is formed together.

### EXAMPLES

The present invention is further explained in more detail with reference to the following examples. These examples, however, should not be interpreted as limiting the scope of the present invention in any manner.

### Examples 1 to 16

### Preparation of Slurry Composition for Primary CMP

First, the following materials were used as the constituents for preparing the slurry composition for primary CMP. As the abrasive, PL-1 or PL-3L among the colloidal silica of Quartron PL series of FUSO CHEMICAL Co. was used, and in order to increase the solubility of the polymeric additives of polyvinylpyrrolidone, 500 ppm of dodecylbenzenesulfonic acid (DBSA) was added to each slurry composition.

According to the compositions disclosed in the following Table 1, the slurry compositions for primary CMP of Examples 1 to 16 were prepared by the following method.

Firstly, the abrasive, the organic acid, the corrosion inhibitor, and the oxidant were introduced into a 1 L polypropylene bottle according to the compositions disclosed in Table 1, and deionized water was added thereto, and then, pH of the slurry composition was controlled using the pH control agent, and the total weight of the composition was adjusted. Finally, the slurry compositions for primary CMP of Examples 1 to 16 were prepared by stirring the composition for 10 minutes at high speed.

TABLE 1
Constituents of Examples 1 to 16

| | Constituents of the slurry | | | | | | |
|---|---|---|---|---|---|---|---|
| | | | Corrosion | | | Polyvinylpyrrolidone | Other polymeric |
| | Abrasive | Organic acid | inhibitor | Oxidant | | Molecular weight | additives |
| Examples | (wt %) | (wt %) | (wt %) | (wt %) | pH | (wt %) | (wt %) |
| 1 | Silica | Glycine (0.5) | Quinaldic | APS(2) | 10.5 | PVP Mw. 3500 (0.1) | — |
| | (1.2) | | acid | | | | |
| | | | (0.3) | | | | |
| 2 | Silica | Glycine (0.5) | DPEA | APS(2) | 10.2 | PVP Mw. 8000 (0.1) | — |
| | (1.2) | malicc acid (0.5) | (0.15) | | | | |
| 3 | Silica | alanine (0.5) | Quinaldic | APS(2) | 10.5 | PVP Mw. 3500 (0.1) | — |
| | (1.5) | | acid | | | | |
| | | | (0.2) | | | | |
| 4 | Silica | alanine (0.5) | Quinaldic | APS(2) | 10.3 | PVP Mw. 3500 (0.1) | — |
| | (1.5) | phthalic acid (0.4) | acid | | | | |
| | | | (0.3) | | | | |
| 5 | Silica | alanine (0.5) | Quinaldic | APS(2) | 10.5 | PVP Mw. 55000 | — |
| | (1.2) | | acid | | | (0.1) | |
| | | | (0.3) | | | | |
| 6 | Silica | Glycine (0.5) | DPEA | APS(2) | 10.5 | PVP Mw. 55000 | — |
| | (1.5) | Pyridine | (0.15) | | | (0.1) | |
| | | carboxylic acid | | | | | |
| | | (0.5) | | | | | |
| 7 | Silica | Glycine (0.5) | DPEA (0.15) | APS(2) | 10.2 | PVP Mw. 8000 | — |
| | (1.5) | Phthalic acid (0.5) | | | | (0.05) | |
| 8 | Silica | Glycine (0.5) | Quinaldic | APS(2) | 10.5 | PVP Mw. 8000 (0.1) | — |
| | (1.5) | Pyridine | acid | | | | |
| | | carboxylic acid | (0.2) | | | | |
| | | (0.5) | | | | | |
| 9 | Silica | Glycine (0.5) | DPEA | APS(2) | 10.2 | PVP Mw. 8000 (0.3) | — |
| | (1.5) | Malic acid (0.5) | (0.15) | | | | |
| 10 | Silica | Glycine (0.5) | DPEA | APS(2) | 10.2 | PVP Mw. 8000 (0.5) | — |
| | (1.5) | Malic acid (0.5) | (0.15) | | | | |
| 11 | Silica | Glycine (0.5) | DPEA | APS(0.2) | 10.5 | PVP Mw. 55000 | Random (0.1) |
| | (1.2) | Pyridine | (0.15) | | | (0.1) | |
| | | carboxylic acid | | | | | |
| | | (0.5) | | | | | |
| 12 | Silica | Glycine (0.5) | Quinaldic | APS(0.2) | 10.5 | PVP Mw. 55000 | F88 (0.2) |
| | (0.5) | Pyridine | acid | | | (0.1) | |
| | | carboxylic acid | (0.2) | | | | |
| | | (0.5) | | | | | |
| 13 | Silica | Glycine (0.5) | Quinaldic | APS(0.2) | 10.5 | PVP Mw. 55000 | Surfynol 485 (0.2) |
| | (0.5) | Phthalic acid (0.5) | acid | | | (0.1) | |
| | | | (0.2) | | | | |
| 14 | Silica | Glycine (0.5) | Quinaldic | APS(0.2) | 10.5 | PVP Mw. 55000 | Random (0.1) |
| | (0.5) | Pyridine | acid | | | (0.02) | |
| | | carboxylic acid | (0.2) | | | | |
| | | (0.5) | | | | | |
| 15 | Silica | Glycine (0.5) | Quinaldic | APS(0.2) | 10.5 | PVP Mw. 55000 | Surfynol 485 (0.2) |
| | (0.5) | Phthalic acid (0.5) | acid | | | (0.005) | |
| | | | (0.2) | | | | |
| 16 | Silica | Glycine (0.5) | Quinaldic | APS(0.2) | 10.5 | PVP Mw. 55000 | Surfynol 485 (0.2) |
| | (0.5) | Phthalic acid (0.5) | acid | | | (0.1) | |
| | | | (0.2) | | | | |

In the Table 1, pH means pH of the slurry that does not include the oxidant, and the pH of the slurry including the oxidant is lowered about 1 to become 9~9.5
In the constituents of Table 1, the remaining content except the contents disclosed in Table 1, and the contents of dodecylbenzenesulfonic acid (DBSA) and the pH control agent not disclosed in Table 1 is water.
In Table 1, DPEA represents 4,4′-dipyridyl ethane, APS represents ammonium persulfate, and PVP represents polyvinylpyrrolidone. And, Random represents a propyleneoxide-ethyleneoxide random copolymer of Aldrich Co., F88 represents a propyleneoxide-ethyleneoxide copolymer of BASF Co., and, Surfynol 485 represents a surfactant of Air product Co. containing 85 wt % of ethyleneoxide.

### Comparative Examples 1 to 3

### Preparation of Slurry Composition for Primary CMP

The slurry compositions for primary CMP of Comparative Examples 1 to 3 were prepared by the same method as in Examples 1 to 16, except that the constituents of the slurry compositions for primary CMP were changed as described in the following Table 2.

TABLE 2
Constituents of Comparative Examples 1 to 3

| | Constituents of the slurry | | | | | | |
|---|---|---|---|---|---|---|---|
| | | | | | | | Other |
| | | | Corrosion | | | | polymeric |
| Comparative | Abrasive | Organic acid | inhibitor | Oxidant | | Polyvinylpyrrolidone | additives |
| Examples | (wt %) | (wt %) | (wt %) | (wt %) | pH | (wt %) | (wt %) |
| 1 | Silica | Glycine (0.5) | Quinaldic acid | APS (2) | 10.5 | — | PEG Mw. 1000 |
| | (1.5) | Malic acid (0.5) | (0.2) | | | | (0.2) |
| 2 | Silica | Glycine (0.5) | DPEA (0.15) | APS (2) | 10.2 | — | |
| | (1.5) | Malic acid (0.5) | | | | | |
| 3 | Silica | Glycine (0.5) | Benzotriazole | APS (2) | 10.5 | PVP Mw. 8000 | |
| | (0.3) | Malic acid (0.5) | (0.00075) | | | (0.1) | |

In the Table 2, pH means the pH of the slurry that does not include the oxidant, and the pH of the slurry including the oxidant is lowered about 1 to become 9~9.5
In the constituents of Table 2, the remaining content except the contents disclosed in Table 2, and the contents of dodecylbenzenesulfonic acid (DBSA) and the pH control agent not disclosed in Table 2 is water.
In the Table 2, DPEA represents 4,4′-dipyridylethane, APS represents ammonium persulfate, and PEG represents polyethyleneglycol.

### Experimental Example

### Tests for the Polishing Property of the Slurry Composition for Primary CMP

The polishing properties were tested by the following method, after carrying out polishing process using the slurry compositions of Examples 1 to 16 and Comparative Examples 1 to 3 as disclosed below.

The wafers on which the target layer as described below was formed were polished by CMP method using the slurry compositions of Examples 1 to 16 and Comparative Examples 1 to 3.

[Target Layer]

6 inches wafer on which a copper layer of 15000 Å was deposited by PVD (Physical Vapor Deposition).

8 inches wafer on which a tantalum layer of 3000 Å was deposited by PVD.

8 inches wafer on which a silicon oxide layer of 7000 Å was deposited by PETEOS.

At this time, the concrete conditions for the polishing were as follows.

[Polishing Condition]: Examples 1 to 10 and Comparative Examples 1 to 3

Polishing device: UNIPLA210 (Doosan Mecatech Co.)

Polishing pad: IC1000/SubaIV Stacked (Rodel Co.)

Platen speed: 24 rpm

Head spindle speed: 100 rpm

Wafer pressure: 1.5 psi

Retainer ring pressure: 2.5 psi

Flow Rate of the slurry: 200 ml/min

[Polishing Condition]: Examples 11 to 16

Polishing device: GnP Poli-500 (G&P Technology, Inc.)

Polishing pad: IC1000/SubaIV Stacked (Rodel Co.)

Platen speed: 93 rpm

Head spindle speed: 87 rpm

Wafer pressure: 1.5 psi

Retainer ring pressure: 3.5 psi

Flow Rate of the slurry: 200 ml/min

The thicknesses of the copper layer, the tantalum layer, and the silicon oxide layer before and after polishing were measured as follows, and the polishing rates (polishing speed: Å/min) of the slurry composition to the copper layer, the tantalum layer, and the silicon oxide layer were obtained from the measured thickness. Also, the polishing selectivity of the slurry composition between the copper layer and the other layers (the polishing selectivity to the copper layer against the tantalum layer or the polishing selectivity to the copper layer against the silicon oxide layer) were calculated from the polishing rates to each layer. The polishing rates to each layer were listed in Tables 3 and 4.

Measuring Method of the Thickness of Each Layer:

The thicknesses of the metal layer of the copper layer or the tantalum layer was calculated according to the following Formula, after measuring the sheet resistance of each layer using LEI1510 Rs Mapping (LEI Co.).

[Thickness of the copper layer (Å)]=[specific resistance of the copper layer (Ω/cm)/sheet resistance (Ω/square(□))]×10⁸

[Thickness of the tantalum layer (Å)]=[specific resistance of the tantalum layer (Ω/cm)/sheet resistance (Ω/square(□))]×10⁸

The thickness of the silicon oxide layer was measured using Nanospec 6100 device (Nanometeics Co.).

In addition, WIWNU (Within Wafer Non-Uniformity) of the target layer (copper layer) after polishing was obtained by establishing 30 points on the wafer on which the copper layer was deposited, and dividing standard deviation of polishing amount measured at each point by average value and multiplying the obtained value by 100.

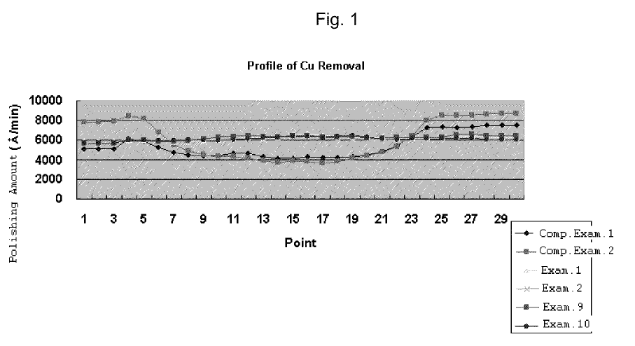

The obtained WIWNU was summarized in the following Tables 3 and 4. And, difference in polishing amount at each point on the wafer when polishing the copper layer using the slurry composition of Examples 1, 2, 9 and 10 and Comparative Examples 1 and 2 was shown in the graph of FIG. 1.

TABLE 3
The results of the polishing properties using the slurry
compositions of Examples 1 to 16

| | | | | WIWNU | Polishing |
|---|---|---|---|---|---|
| | | | | of | rate to |
| | Polishing rate (Å/min) | | | polished | copper layer/ |
| | | | Silicon | copper | Polishing |
| | Copper | Tantalum | oxide | layer | rate to |
| Examples | layer | layer | layer | (%) | tantalum layer |
| 1 | 6176 | 117 | 30 | 3.41 | 53 |
| 2 | 6085 | 107 | 28 | 3.36 | 57 |
| 3 | 4600 | 85 | 35 | 4.16 | 54 |
| 4 | 4300 | 109 | 24 | 3.56 | 39 |
| 5 | 4050 | 88 | 24 | 2.37 | 46 |
| 6 | 6287 | 109 | 30 | 3.32 | 58 |
| 7 | 6176 | 93 | 29 | 4.72 | 66 |
| 8 | 6085 | 79 | 25 | 4.68 | 77 |
| 9 | 6230 | 107 | 17 | 3.35 | 58 |
| 10 | 6210 | 84 | 18 | 3.11 | 74 |
| 11 | 10810 | 20 | 18 | 4.21 | 541 |
| 12 | 10450 | 15 | 16 | 1.77 | 697 |
| 13 | 11050 | 17 | 20 | 2.57 | 650 |
| 14 | 10120 | 52 | 19 | 5.00 | 195 |
| 15 | 10500 | 130 | 21 | 4.95 | 81 |
| 16 | 10030 | 48 | 18 | 4.20 | 209 |

TABLE 4
The results of the polishing properties using the slurry compositions
of Comparative Examples 1 to 3

| | | | | | Polishing |
|---|---|---|---|---|---|
| | | | | | rate to |
| | | | | WIWNU | copper |
| | | | | of | layer/ |
| | | | | polished | Polishing |
| | Polishing rate (Å/min) | | | copper | rate to |
| Comparative | Copper | Tantalum | Silicon | layer | tantalum |
| Examples | layer | layer | oxide layer | (%) | layer |
| 1 | 6537 | 130 | 31 | 25.82 | 50 |
| 2 | 6085 | 107 | 30 | 34.87 | 57 |
| 3 | 218 | 53 | 15 | 15.8 | 4 |

Referring to the above Tables 3 and 4 and FIG. 1, it is confirmed that low polishing rate to the tantalum layer and the silicon oxide layer, particularly to the tantalum layer can be obtained to exhibit excellent polishing selectivity of polishing rate between the copper layer:the tantalum layer of 30:1 or more, while maintaining excellent polishing rate to the target layer (copper layer) of 4000 Å/min or more, using the slurry compositions of Examples 1 to 16 comprising a polyvinylpyrrolidone polymeric additive and a corrosion inhibitor of a pyrazole-based, a pyridine-based or a quinoline-based compound.

Particularly, in the case where an additional polymeric additive such as a propyleneoxide-ethyleneoxide copolymer is used together with the polyvinylpyrrolidone, more excellent polishing rate and selectivity to the copper layer can be obtained.

It is also confirmed that excellent WIWNU (Within Wafer Non-Uniformity) of the polished copper layer of 5% or less can be maintained, using the slurry compositions of Examples 1 to 16.

To the contrary, it is confirmed that when the slurry compositions of Comparative Examples 1 and 2 that does not include the polyvinylpyrrolidone are used, although polishing rate and polishing selectivity to the target layer are relatively excellent, WIWNU of the polished copper layer is 25% or more, indicating that polishing variation is very large at each point on the wafer to show excessive polishing to the target layer (copper layer) particularly at the edge of the wafer. Thus, if the slurry compositions of Comparative Examples 1 and 2 are used, it is expected that the copper layer is excessively polished and excessively removed at the edge of the wafer to deteriorate electrical property of the polished copper layer and generate more dishing and erosion, etc.

It is also confirmed that when the slurry composition of Comparative Example 3 comprising benzotriazole as a corrosion inhibitor is used, polishing rate and polishing selectivity to the copper layer is low and thus appropriate properties for use as the slurry for primary CMP of the copper layer cannot be obtained and WIWNU is much inferior to the Examples.

What is claimed is:

1. A slurry composition for primary chemical mechanical polishing: comprising an abrasive; an oxidant, an organic acid; a corrosion inhibitor and, a polymeric additive comprising polyvinylpyrrolidone having a weight average molecular weight of about 3,000 to 100,000, wherein the composition has a polishing selectivity between a copper layer:a tantalum layer of about 30:1 or more; and wherein the corrosion inhibitor is selected from the group consisting of a pyridine-based compound, a pyrazole-based compound and a quinoline-based compound.

2. The slurry composition according to claim 1, wherein the composition has a polishing rate to the copper layer of about 3000 Å/min or more.

3. The slurry composition according to claim 1, wherein the copper layer after polished has WIWNU (Within Wafer Non-Uniformity) of about 5% or less.

4. The slurry composition according to claim 1, wherein the abrasive comprises at least one selected from the group consisting of a silica abrasive, an alumina abrasive, a ceria abrasive, a zirconia abrasive, a titania abrasive, a styrene-based polymer abrasive, an acryl-based polymer abrasive, a polyvinyl chloride abrasive and a polyamide abrasive.

5. The slurry composition according to claim 1, wherein the abrasive has an average particle diameter of about 10 to 500 nm.

6. The slurry composition according to claim 1, wherein the oxidant comprises at least one selected from the group consisting of hydrogen peroxide, peracetic acid, perbenzoic acid, tert-butylhydroperoxide, ammonium persulfate (APS), potassium persulfate (KPS), hypochlorous acid, potassium permanganate, iron nitrate, potassium ferricyanide, potassium periodate, sodium hypochlorite, vanadium trioxide, and potassium bromate.

7. The slurry composition according to claim 1, wherein the organic acid comprises at least one amino acid selected from the group consisting of alanine, glycine, cystine, histidine, and a salt thereof.

8. The slurry composition according to claim 1, wherein the organic acid comprises at least one amine-based compound selected from the group consisting of asparagine, guanidine, hydrazine, ethylene diamine, and a salt thereof.

9. The slurry composition according to claim 1, wherein the organic acid comprises at least one carboxylic acid compound selected from the group consisting of maleic acid, malic acid, tartaric acid, citric acid, malonic acid, phthalic acid, acetic acid, lactic acid, pyridine carboxylic acid, pyridine dicarboxylic acid, and a salt thereof.

10. The slurry composition according to claim 1, wherein the corrosion inhibitor comprises at least one selected from the group consisting of 4,4′-dipyridyl ethane, 4,4′-dipyridyl ethene, 4,4′-dipyridyl propane, 4,4′-dipyridyl propene, 3,5-pyrazole dicarboxylic acid, quinaldic acid, 2-quinazoline carboxylic acid, 4-quinazoline carboxylic acid, 2-quinoline carboxaldehyde, 8-quinolinol, 2-quinolinol, and a salt thereof.

11. The slurry composition according to claim 1, wherein the polymeric additive further comprises at least one polymer selected from the group consisting of propyleneoxide-ethyleneoxide copolymer, polyethyleneglycol and polyoxyethylene ether.

12. The slurry composition according to claim 1, further comprising dodecylbenzene sulfonic acid or dodecylsulfate.

13. The slurry composition according to claim 1, further comprising a pH control agent.

14. The slurry composition according to claim 13, wherein the pH control agent comprises at least one basic pH control agent selected from the group consisting of potassium hydroxide, sodium hydroxide, aqueous ammonia, rubidium hydroxide, cesium hydroxide, sodium hydrogen carbonate, and sodium carbonate; or at least one acidic pH control agent selected from the group consisting of hydrochloric acid, nitric acid, sulfuric acid, phosphoric acid, formic acid, and acetic acid.

15. The slurry composition according to claim 13, wherein the composition comprises about 0.1 to 30 wt % of the abrasive, about 0.1 to 10 wt % of the oxidant, about 0.05 to 2 wt % of the organic acid, about 0.001 to 2 wt % of the corrosion inhibitor, and about 0.0001 to 1 wt % of the polymeric additive, based on the total weight of the composition.

16. The slurry composition according to claim 1, wherein the composition is used for primary chemical mechanical polishing of a copper-containing layer.

17. The slurry composition according to claim 16, wherein the copper-containing layer comprises a copper wiring layer of a semiconductor device.

18. A chemical mechanical polishing method comprising:
contacting a polishing pad with a copper-containing layer on a substrate; and
moving them relative to each other while providing the slurry composition according to claim 1 between the copper-containing layer on the substrate and the polishing pad to primarily polish the copper-containing layer.

19. The chemical mechanical polishing method according to claim 18, further comprising:
contacting a polishing pad with the primarily polished copper-containing layer; and
moving them relative to each other while providing a slurry composition for secondary chemical mechanical polishing between the primarily polished copper-containing layer and the polishing pad to secondarily polish the copper-containing layer.

20. The chemical mechanical polishing method according to claim 18, wherein the copper-containing layer comprises a polishing stop layer and a copper wiring layer on the substrate, and the primary polishing is performed until an upper surface of the polishing stop layer is exposed.

21. The chemical mechanical polishing method according to claim 20, wherein the polishing stop layer comprises a tantalum-containing layer.

22. The chemical mechanical polishing method according to claim 18, comprising contacting the polishing pad with the copper-containing layer and rotating the substrate on the polishing pad without rotating the polishing pad to polish the copper-containing layer on the substrate.

23. The chemical mechanical polishing method according to claim 18, comprising contacting the polishing pad with the copper-containing layer and rotating the polishing pad and the substrate to polish the copper-containing layer on the substrate.

24. The chemical mechanical polishing method according to claim 19, comprising contacting the polishing pad with the copper-containing layer and rotating the substrate on the polishing pad without rotating the polishing pad to polish the copper-containing layer on the substrate.

25. The chemical mechanical polishing method according to claim 19, comprising contacting the polishing pad with the copper-containing layer and rotating the polishing pad and the substrate to polish the copper-containing layer on the substrate.
